(19) United States
(12) Patent Application Publication
(10) Pub. No.: US 2016/0064441 A1
(43) Pub. Date: Mar. 3, 2016

(54) SOLID IMAGING DEVICE

(71) Applicant: KABUSHIKI KAISHA TOSHIBA, Tokyo (JP)

(72) Inventors: Hiroki SASAKI, Yokohama Kanagawa (JP); Koichi KOKUBUN, Yokohama Kanagawa (JP)

(73) Assignee: KABUSHIKI KAISHA TOSHIBA, Tokyo (JP)

(21) Appl. No.: 14/610,692

(22) Filed: Jan. 30, 2015

(30) Foreign Application Priority Data
Aug. 27, 2014 (JP) 2014-173062

(51) Int. Cl. H01L 27/146

(52) U.S. Cl. CPC H01L 27/14636; H01L 27/14621; H01L 27/14623; H01L 27/1462; H01L 27/14627

(57) ABSTRACT

A solid imaging device to an embodiment includes a semiconductor substrate and a conductive film. The semiconductor substrate has a plurality of photoelectric conversion elements constituting a plurality of pixels formed therein, the semiconductor substrate having a first surface and a second surface opposite to the first surface and being equipped with a wire layer on a first surface side of the semiconductor substrate. The conductive film is patterned and arranged above a border between pixels of the plurality of pixels on a second surface side of the semiconductor substrate. The conductive film is substantially transparent to visible light.

### CROSS-REFERENCE TO RELATED APPLICATION

This application is based upon and claims the benefit of priority from Japanese Patent Application No. 2014-173062 filed on Aug. 27, 2014 in Japan, the entire contents of which are incorporated herein by reference.

### FIELD

Embodiments described herein relate generally to a solid imaging device.

### BACKGROUND

Solid imaging devices include a CCD image sensor and a CMOS (Complementary Metal Oxide Semiconductor) image sensor in which photodiodes to be photoelectric conversion elements are formed on a silicon (Si) wafer by separately creating PN impurity regions through ion implantation of donors (such as phosphorus or arsenic) or acceptors (such as boron) in the Si wafer. In recent years, with the development of semiconductor fabrication technology, backside illumination-type CMOS image sensors have been under development. A backside illumination-type CMOS image sensor is fabricated by forming photoelectric conversion elements and then pasting a circuit forming surface of an Si wafer having a circuit such as a wire layer formed on the photoelectric conversion elements to a support substrate and cutting the backside of the Si wafer thin to let light into elements from the opposite side of the wire layer. Thus, light can be let into a device without being affected by the wire layer. Therefore, light can be let into the device efficiently. In the backside illumination-type CMOS image sensor, however, charging due to static electricity generated during processes of semiconductor fabrication could pose a problem.

### BRIEF DESCRIPTION OF THE DRAWINGS

FIG. 1 is a sectional view of a solid imaging device according to a first embodiment;

FIG. 2 is a diagram showing an example of an arrangement position of a conductive film according to the first embodiment;

FIG. 3 is a diagram showing another example of the arrangement position of the conductive film according to the first embodiment;

FIG. 4 is a diagram showing still another example of the arrangement position of the conductive film according to the first embodiment;

FIG. 5 is a flow chart showing principal processes of a method for fabricating a solid imaging device according to the first embodiment;

FIG. 6 is a diagram showing an example of a cross section of the solid imaging device before an antireflection film according to the first embodiment is formed;

FIG. 7 is a process sectional view of the method for fabricating a solid imaging device according to the first embodiment;

FIG. 8 is a process sectional view of the method for fabricating a solid imaging device according to the first embodiment;

FIG. 9 is a process sectional view of the method for fabricating a solid imaging device according to the first embodiment;

FIG. 10 is a process sectional view of the method for fabricating a solid imaging device according to the first embodiment; and

FIG. 11 is a process sectional view of the method for fabricating a solid imaging device according to the first embodiment.

### DETAILED DESCRIPTION

### First Embodiment

A solid imaging device according to an embodiment includes a semiconductor substrate and a conductive film. The semiconductor substrate has a plurality of photoelectric conversion elements constituting a plurality of pixels formed therein, the semiconductor substrate having a first surface and a second surface opposite to the first surface and being equipped with a wire layer on a first surface side of the semiconductor substrate. The conductive film is patterned and arranged above a border between pixels of the plurality of pixels on a second surface side of the semiconductor substrate. The conductive film is substantially transparent to visible light.

In the first embodiment described below, a solid imaging device capable of efficiently letting in light while inhibiting charging due to static electricity will be described.

In the first embodiment described below, a solid imaging device using a photodiode (PD) will be described as an example of a photoelectric conversion element. However, the photoelectric conversion element described below is not limited to a case in which the photodiode (PD) is used and also applies when a photoelectric conversion element such as a phototransistor is used. The first embodiment will be described below using the drawings.

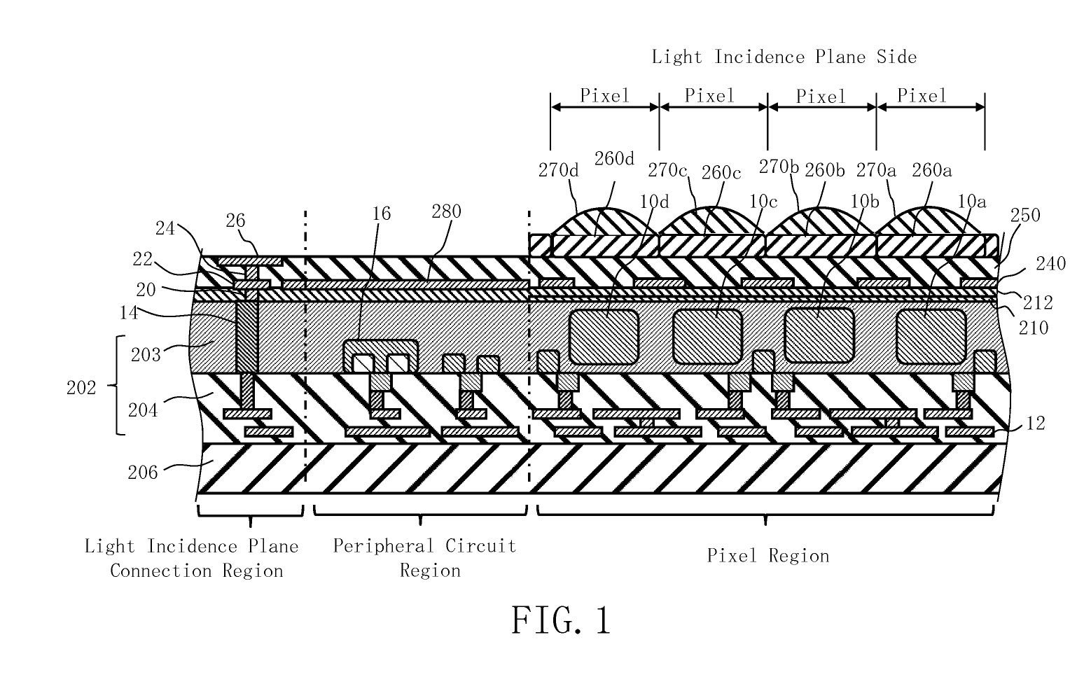

FIG. 1 is a sectional view of a solid imaging device according to the first embodiment. FIG. 1 shows an example of the cross section of a pixel region in which a plurality of photodiodes 10a to 10d that receives light to perform a photoelectric conversion is arranged, a peripheral circuit region in which a peripheral circuit 16 is arranged, and a light incidence plane connection region that connects a wire layer and a light incidence plane. Each sectional view including FIG. 1 describes as a light incidence plane side is upper.

The plurality of photodiodes 10a to 10d are formed inside a semiconductor substrate 202 using silicon (Si). Specifically, the plurality of photodiodes 10a to 10d are formed in a Si layer 203 of the semiconductor substrate 202. In the example of FIG. 1, the plurality (four) of photodiodes 10a to 10d are shown in the pixel region by being aligned in a row, but is arranged regularly in two dimensions like longitudinal and lateral directions (x and y directions). Each of the photodiodes 10 forms one pixel. In this manner, the plurality of photodiodes 10a to 10d (photoelectric conversion elements) constituting a plurality of pixels are arranged inside the semiconductor substrate 202. A floating diffusion (FD) region as a charge accumulation portion to which charges photoelectrically converted by two photodiodes 10 are transferred is formed inside the semiconductor substrate 202 between the two photodiodes 10 neighboring in the column direction. In the peripheral circuit region, the peripheral circuit 16 such as a resistance element and a MOS transistor is formed. In the light incidence plane connection region, a plug 14 penetrating through the Si layer 203 of the semiconductor substrate 202 is formed.

A wire layer 204 in which a wire 12 is arranged is formed on the Si layer 203 of the semiconductor substrate 202 (in FIG. 1, the undersurface side) in which the plurality of photodiodes 10a to 10d are formed. The wire layer 204 is arranged on a side (a first surface side) of the semiconductor substrate 202 opposite to a side of the light incidence plane (a second surface side). In the peripheral circuit region, the wire layer 204 is arranged on the peripheral circuit 16. In the light incidence plane connection region, the wire layer 204 is formed on the plug 14. In the wire layer 204, the wire 12 and a contact plug, a via plug and the like that connect upper and lower wires are formed in an interlayer dielectric film. Thus the semiconductor substrate 202 includes a Si layer 203 in which the plurality of photodiodes 10a to 10d are formed on the side of the light incidence plane, and is equipped with the wire layer 204 on a rear side of the light incidence plane.

Then, a support substrate 206 is pasted to the surface on the side of the wire layer 204 (first surface side) of the semiconductor substrate 202 on which the wire layer 204 is formed. Then, while mechanically strengthened, the backside (second surface side) of the semiconductor substrate 202 is thinned to a desired thickness allowing light to enter the plurality of photodiodes 10a to 10d from the backside.

In a front side illumination-type solid imaging device, a wire layer is present between the incidence plane where light enters and a photoelectric conversion element and thus, charging due to static electricity generated during processes of semiconductor fabrication does not occur or less likely to occur. In a backside illumination-type solid imaging device, by contrast, a space between a microlens 270 as an incidence plane and a receiving surface of the photodiode 10 as a photoelectric conversion element is configured almost entirely by an insulator in the pixel region where light enters. Thus, charging can occur between the microlens 270 and the receiving surface of the photodiode 10 due to static electricity generated during processes of semiconductor fabrication. Therefore, in a backside illumination-type solid imaging device, a problem specific thereto arises that is different from that of a front side illumination-type solid imaging device. Thus, in the first embodiment, charging is inhibited by arranging a conductive film 240 between the microlens 270 and the receiving surface of the photodiode 10. Addressing such a problem by coating the entire surface of the incidence plane (for example, the microlens) of the solid imaging device with an optically transparent conductive film to prevent charging can be considered, but in such a case, it is difficult to prevent charging due to static electricity generated in processes of semiconductor fabrication between a substrate process and a microlens formation process. In addition, even if the conductive film is optically transparent, it is difficult to transmit incident light completely, undermining the advantage of translucency increased by receiving light from the opposite side of the wire layer. In the first embodiment, therefore, the conductive film 240 is patterned and arranged such that light can efficiently enter the space between the microlens 270 and the receiving surface of the photodiode 10. A concrete example will be described below.

An antireflection film 210 is formed on the opposite surface of the surface on which the wire layer 204 of the semiconductor substrate 202 is formed to a thickness of, for example, 15 nm in the pixel region. A dielectric film such as tantalum oxide (TaO) and hafnium oxide (HfO) can suitably be used as the material of the antireflection film 210. Using conductive titanium oxide (TiO₂) can also be considered, but in such a case, the thickness of the antireflection film 210 is limited to ensure the transmittance as an imaging device. Due to such a limitation, it is difficult to form a conductive antireflection film thick enough to remove charging. Therefore, if TiO is used for the antireflection film 210, it is difficult to remove charging sufficiently.

In the pixel region, a dielectric film 212 to be a foundation film is formed on the antireflection film 210 to a thickness of, for example, 100 nm. On the other regions, the dielectric film 212 is formed on the semiconductor substrate 202.

In the pixel region, the conductive film 240 that is substantially transparent to visible light is arranged on the dielectric film 212. In other words, the conductive film 240 is formed above the opposite surface of the surface on which the wire layer 204 of the semiconductor substrate 202 is formed. As the conductive film 240, for example, an InGaZnO film (IGZO film) as an oxide of indium (In), gallium (Ga), and zinc (Zn) is suitably used. In addition to the InGaZnO film, an InZnO film, a ZnO film, an InO film, a GaZnO film, an indium tin oxide (ITO) film, a tin oxide (SnO₂) film, or a TiO₂ film can also be used. Among these films, oxides including In are desirable from the viewpoint of the transmittance of light. Particularly, the InGaZnO film is more desirable. By adopting the InGaZnO film, the optical absorption of transmitted light can be controlled to about 10%. The conductive film 240 is formed thicker than the antireflection film 210 and is suitably formed to a thickness of, for example, 20 nm or more. Here, the conductive film is formed to a thickness of, for example, 100 nm.

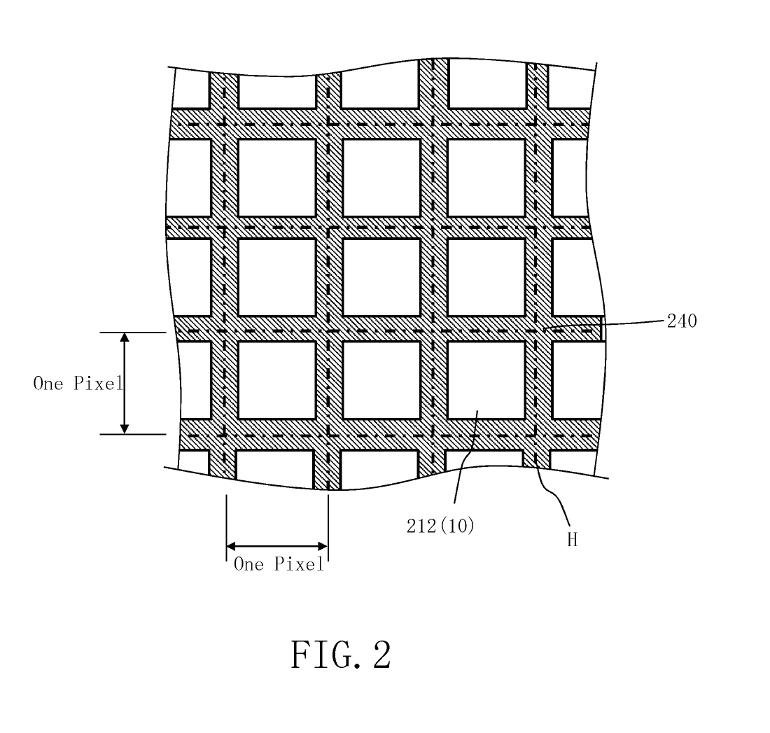

FIG. 2 is a diagram showing an example of an arrangement position of the conductive film according to the first embodiment. As shown in FIG. 2, the conductive film 240 is arranged above a border H between pixels of a plurality of pixels. In the example of FIG. 2, the conductive film 240 is patterned and formed in a grid shape and arranged between the plurality of photodiodes 10 arranged regularly in n rows×m columns. The example of FIG. 2 shows a case when the conductive film 240 is formed such that the unit region of each pixel shown in a region where the dielectric film 212 is exposed is rectangular. In the first embodiment, each region surrounded in a grid shape by each center line between the neighboring photodiodes 10 in the lateral direction (row direction: x direction) and each center line between the neighboring photodiodes 10 in the longitudinal direction (column direction: y direction) is defined as a region of pixel.

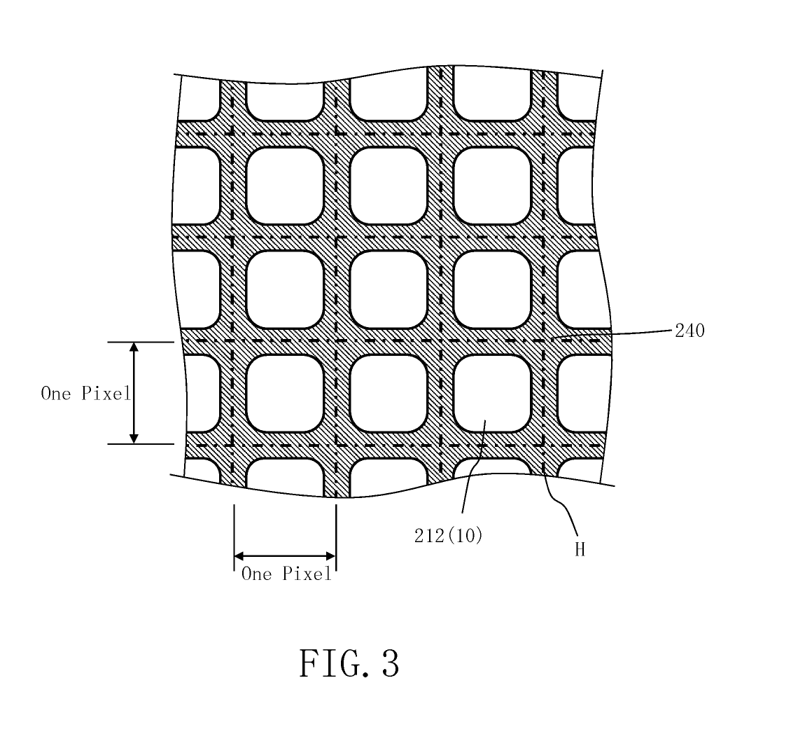

FIG. 3 is a diagram showing another example of the arrangement position of the conductive film according to the first embodiment. The example of FIG. 3 shows a case when the conductive film 240 is formed above the border H between pixels of a plurality of pixels such that four corners of the unit region of each pixel shown in a region where the dielectric film 212 is exposed form an arc-like smooth curve.

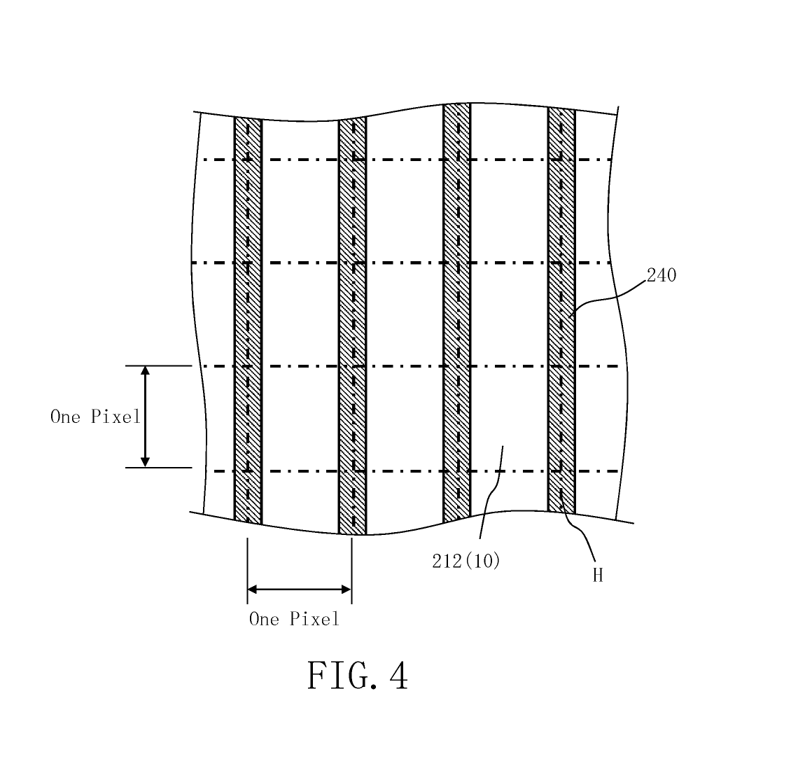

FIG. 4 is a diagram showing still another example of the arrangement position of the conductive film according to the first embodiment. In the example of FIG. 4, the conductive film 240 is arranged linearly above the border H between pixels of a plurality of pixels aligned in the longitudinal direction (column direction: y direction) of borders of the plurality of photodiodes 10 arranged regularly in n rows×m columns. In the example of FIG. 4, a case when the conductive film 240 is formed in the longitudinal direction (column direction: y direction) is shown, but the conductive film may also be patterned and formed in a line shape or “linearly” and arranged above the border H between pixels of a plurality of pixels aligned in the lateral direction (row direction: x direction).

In the peripheral circuit region, a light shielding film 280 is arranged on the dielectric film 212. In the light incidence plane connection region, a contact plug 20 and a wire 22 connected to the plug 14 are formed.

In the pixel region, a dielectric film 250 is formed on the conductive film 240 formed above the border H between pixels and on a region where the conductive film 240 is not formed and the dielectric film 212 is exposed to a thickness of, for example, 100 nm to 200 nm. In the peripheral circuit region, the dielectric film 250 is formed on the light shielding film 280. In the light incidence plane connection region, the dielectric film 250 is formed on the wire 22. Also in the light incidence plane connection region, a wire 26 is formed on the surface of the dielectric film 250. In addition, a contact plug 24 connecting the wire 22 and the wire 26 is formed in the dielectric film 250.

In the pixel region, color filter films 260a to 260d are formed in the unit region of each pixel on the dielectric film 250. In addition, the microlenses 270 (270a to 270d) are formed on the color filter films 260 (260a to 260d) of each pixel respectively.

By patterning and arranging the conductive film 240 above the border H between pixels of a plurality of pixels as described above, the deterioration of transmittance due to the conductive film 240 can be inhibited and the reduction of the amount of light entering the photodiode 10 can be inhibited. Incidentally, the conductive film 240 is formed so as to be in an electrically floating structure. Even the floating structure can achieve a mirror image effect and a local electric field concentration in the pixel region can be controlled. Therefore, light can efficiently be let in the photodiode 10 while inhibiting charging due to static electricity generated in the pixel region.

The conductive film 240 may be connected to a power source line such as GND to supply a predetermined potential and also in this case, charging due to static electricity can be inhibited. In the first embodiment, therefore, charging can be inhibited by the conductive film 240 and image spots due to noise of a dark current that flows even if no light is incident can be inhibited or reduced.

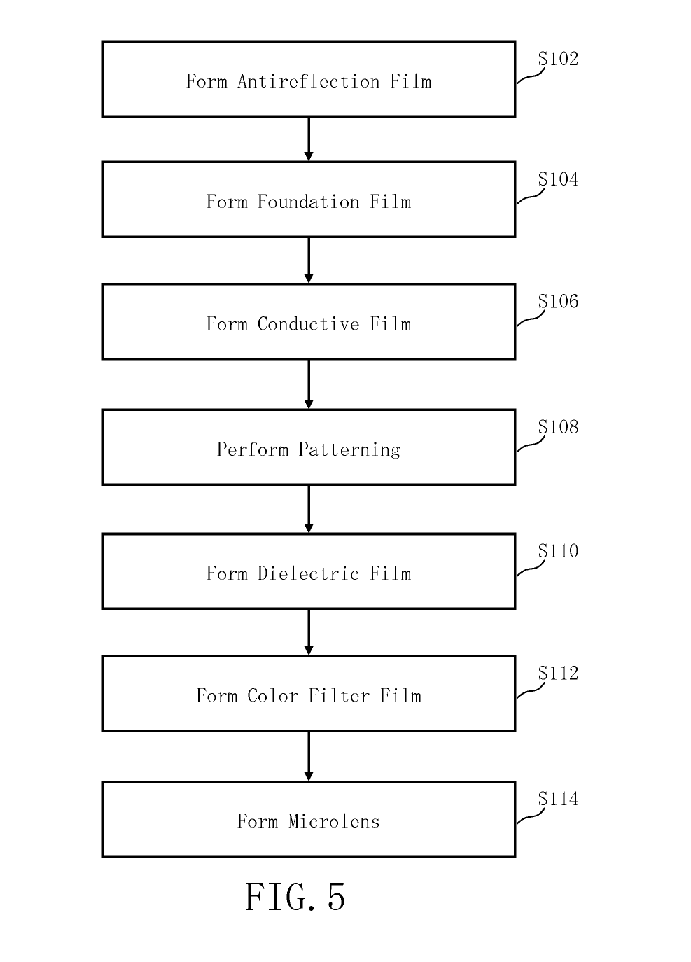

FIG. 5 is a flow chart showing principal processes of a method for fabricating a solid imaging device according to the first embodiment. In FIG. 5, the method for fabricating a solid imaging device according to the first embodiment executes a series of processes including an antireflection film formation process (S102), a foundation film formation process (S104), a conductive film formation process (S106), a patterning process (S108), a dielectric film formation process (S110), a color filter film formation process (S112), and a microlens formation process (S114).

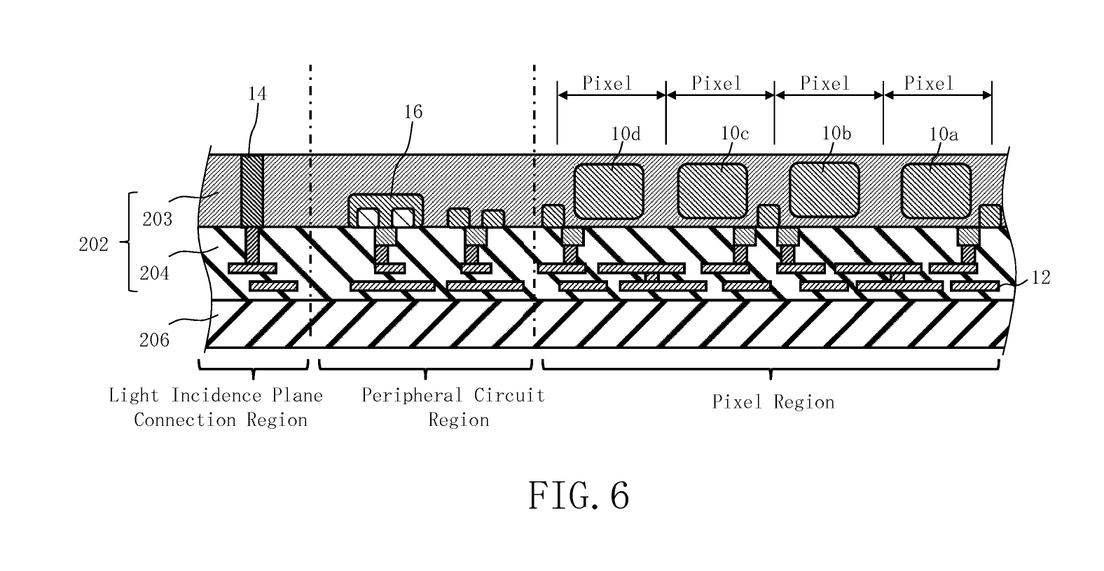

FIG. 6 is a diagram showing an example of the cross section of the solid imaging device before an antireflection film according to the first embodiment is formed. In FIG. 6, as described above, the plurality of photodiodes 10a to 10d are formed inside the Si layer 203 of the semiconductor substrate 202. Each of the photodiodes 10 forms one pixel. The plurality of photodiodes 10a to 10d may be performed element isolation by injecting impurities between the photodiodes. In the peripheral circuit region, the peripheral circuit 16 such as a resistance element and a MOS transistor is formed. In the light incidence plane connection region, the plug 14 penetrating through the Si layer 203 of the semiconductor substrate 202 is formed. Then, the wire layer 204 is formed on the Si layer 203 of the semiconductor substrate 202 and the support substrate 206 is pasted to the surface on the side of the wire layer 204. Then, the backside of the semiconductor substrate 202 is polished to a desired thickness allowing light to enter the plurality of photodiodes 10a to 10d from the backside. The fabrication processes heretofore may be the same as in the past. In the first embodiment, the method for fabricating a solid imaging device hereafter will be described.

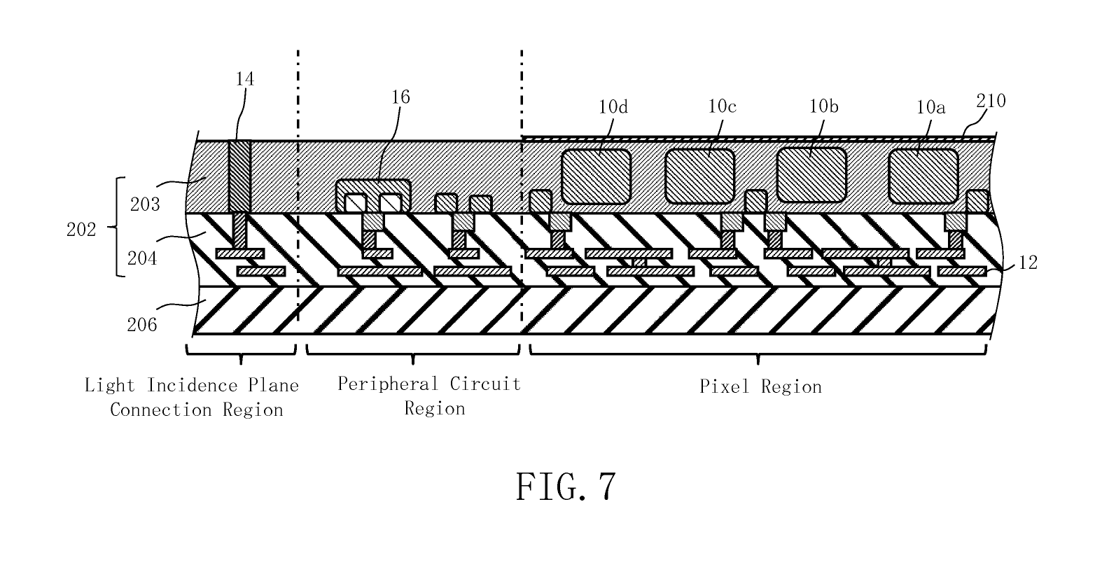

FIG. 7 is a process sectional view of the method for fabricating a solid imaging device according to the first embodiment. In FIG. 7, the antireflection film formation process (S102) in FIG. 5 is shown. Subsequent processes will be described later.

In FIG. 7, as the antireflection film formation process (S102), the antireflection film 210 is formed on the opposite surface (backside) of the surface on which the wire layer 204 of the semiconductor substrate 202 is formed to a thickness of, for example, 15 nm in the pixel region. The chemical vapor deposition (CVD) method or the atomic layer deposition (ALD, or the atomic layer chemical vapor deposition (ALCVD)) method is suitably used as the formation method. The antireflection film 210 may be formed in the pixel region by removing the antireflection film 210 exposed in the other regions than the pixel region by the anisotropic etching method from the semiconductor substrate 202 on which a resist pattern is formed by undergoing the lithography process such as a resist application process and an exposure process (not shown).

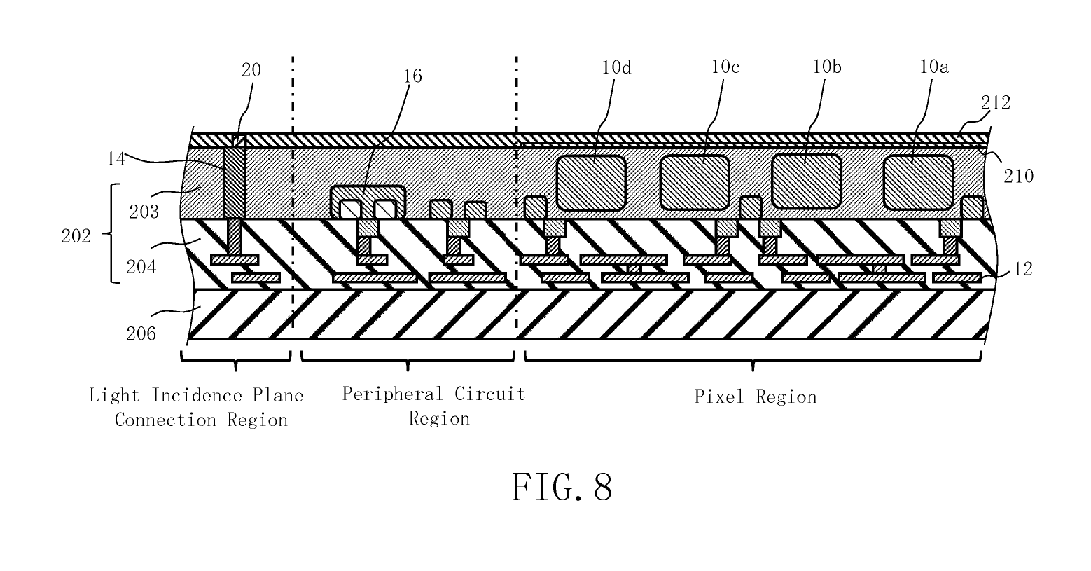

FIG. 8 is a process sectional view of the method for fabricating a solid imaging device according to the first embodiment. In FIG. 8, the foundation film formation process (S104) in FIG. 5 is shown. Subsequent processes will be described later.

In FIG. 8, as the foundation film formation process (S104), the dielectric film 212 to be a foundation film is formed on the antireflection film 210 in the pixel region and on the semiconductor substrate 202 in the other regions by using the CVD method. As the dielectric film 212, for example, a silicon oxide (SiO₂) film is formed.

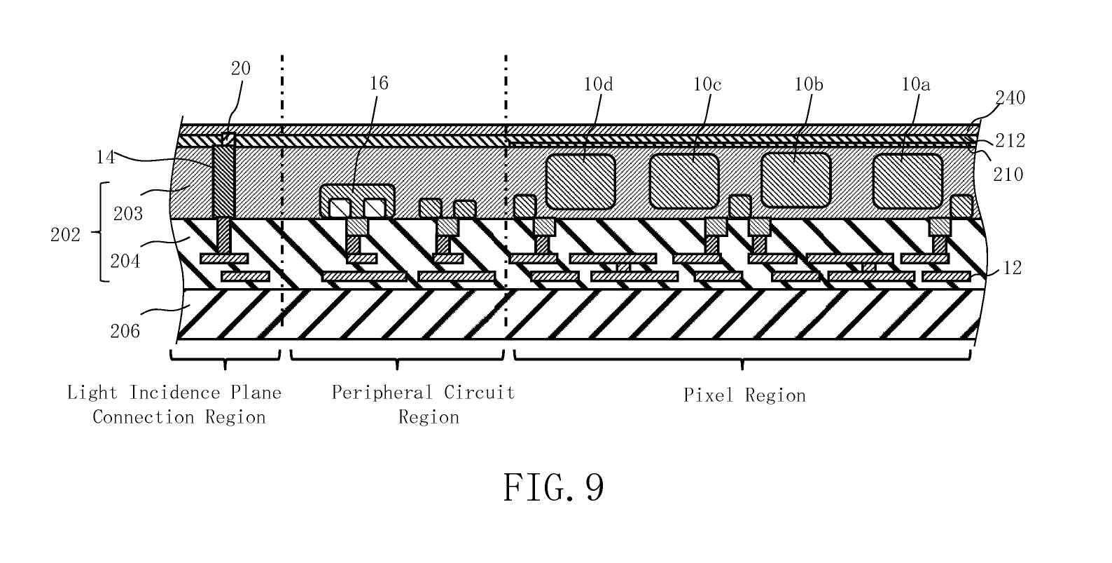

FIG. 9 is a process sectional view of the method for fabricating a solid imaging device according to the first embodiment. In FIG. 9, the conductive film formation process (S106) in FIG. 5 is shown. Subsequent processes will be described later.

In FIG. 9, as the conductive film formation process (S106), the conductive film 240 is formed on the dielectric film 212 by using, for example, the sputter process to a thickness of, for example, 20 nm or more, preferably 50 nm or more and 300 nm or less. Here, the IGZO film is formed to a thickness of, for example, 100 nm.

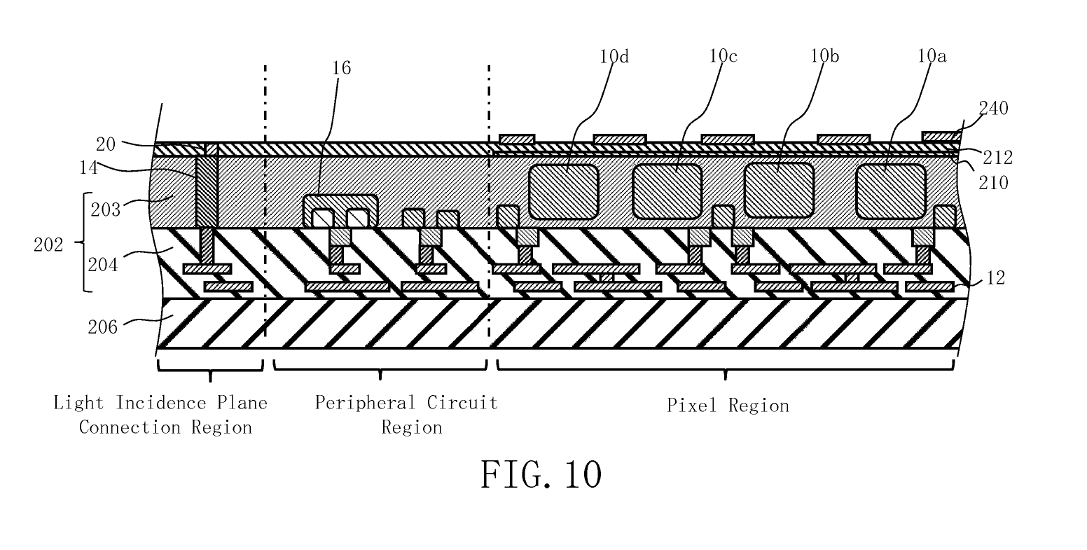

FIG. 10 is a process sectional view of the method for fabricating a solid imaging device according to the first embodiment. In FIG. 10, the patterning process (S108) in FIG. 5 is shown. Subsequent processes will be described later.

In FIG. 10, as the patterning process (S108), the conductive film 240 exposed in regions other than above the border H between pixels of a plurality of pixels is removed by, for example, the reactive ion etching (RIE) method from the semiconductor substrate 202 on which a resist pattern is formed by undergoing the lithography process such as a resist application process and an exposure process (not shown). Accordingly, as shown in any of FIGS. 2 to 4, the conductive film 240 is patterned above the border H between pixels of pixels in a grid shape or linearly. As an etching gas, for example, an organic gas such as CH₄ or a halogen gas such as HI can be used. In addition to the dry etching method such as the RIE method, a wet etching method may also be used. When, for example, an IGZO film is used as the conductive film 240, for example, oxalic acid can be used as etchant. When, for example, an ITO film is used, for example, a mixed liquid of hydrochloric acid and nitric acid can be used as etchant.

In the first embodiment, the dielectric film 212 is formed as a foundation film and thus, the antireflection film 210 can be prevented from being removed by etching. However, the present embodiment is not limited to such a case and the conductive film 240 may be formed directly on the antireflection film 210 without the dielectric film 212 therebetween.

In the peripheral circuit region, for example, the light shielding film 280 using aluminum (Al) is formed.

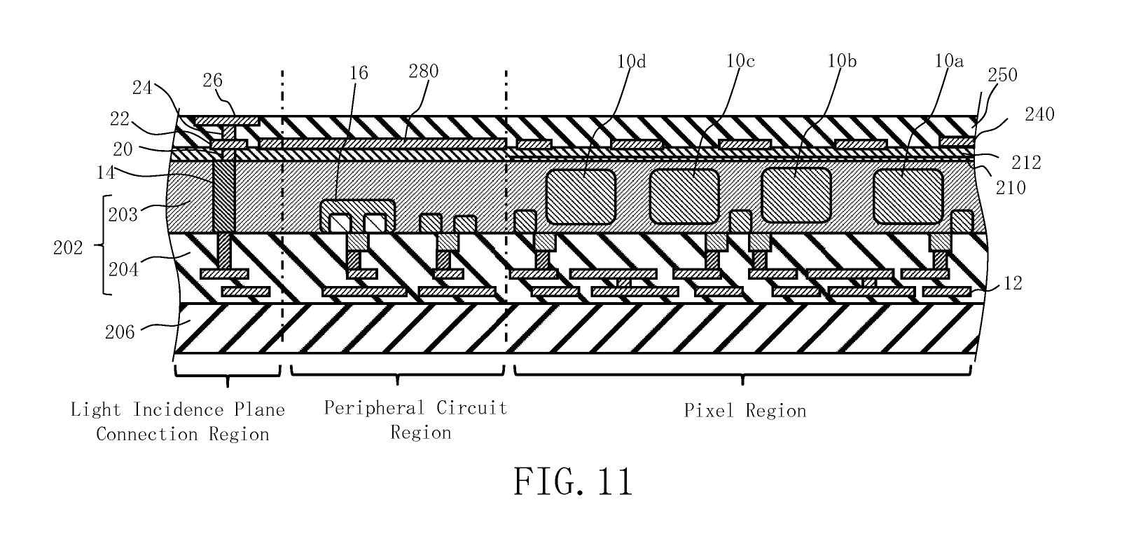

FIG. 11 is a process sectional view of the method for fabricating a solid imaging device according to the first embodiment. In FIG. 11, the dielectric film formation process (S110) in FIG. 5 is shown. Subsequent processes will be described later.

In FIG. 11, as the dielectric film formation process (S110), the dielectric film 250 is formed on the conductive film 240 and the dielectric film 212 in the pixel region, on the light shielding film 280 in the peripheral circuit region, and on the dielectric film 212 in the other region by using the CVD method. As the dielectric film 250, for example, an SiO₂ film is formed.

As the color filter film formation process (S112), the color filter film 260 (260a to 260d) including the selected pigmented layer from red (R), green (G), blue (B), yellow (Y), cyan (C), and magenta (M) is formed on each pixel in the pixel region. The method for forming the color filter film 260 may be the same as the conventional method.

As the microlens formation process (S114), the microlenses 270 (270a to 270d) are formed on the respective color filter films 260 (260a to 260d) of each pixel in the pixel region. After a film of photosensitive resin is formed on the color filter film 260, the film is patterned to, for example, a rectangular shape (island shape) by fitting to the shape of the unit region of each pixel. Then, the photosensitive resin formed in a rectangular shape is melted by heating and treating the resin to transform a film having a convex curved surface due to surface tension. Then, the transformed film may be hardened to form the microlens 270 for each pixel. By performing each process as described above, a solid imaging device shown in FIG. 1 can be fabricated. Incidentally, a detailed process description of the peripheral circuit region and the light incidence plane connection region is omitted.

According to the first embodiment, as described above, charging generated in the pixel region can be inhibited by the conductive film 240. In addition, the deterioration of transmittance of light can be inhibited by forming the conductive film 240 by avoiding the receiving surface of each pixel.

Further in the first embodiment, by arranging the conductive film 240 between, for example, the dielectric film 212 and the dielectric film 250, instead of on the microlens 270, the surface of which is a convex curved surface, the conductive film 240 can be formed on a flat surface of the foundation film, making patterning easier.

The embodiment is described above with reference to the concrete examples. However, the embodiment is not limited to such concrete examples. In the above example, for example, the conductive film 240 is formed between the dielectric film 212 and the dielectric film 250, but the embodiment is not limited to such an example. The conductive film may be arranged in another position between the microlens 270 and the semiconductor substrate 202. Particularly from the viewpoint of ease of patterning the conductive film 240, also when the conductive film 240 is formed between the semiconductor substrate 202 and the antireflection film 210, between the antireflection film 210 and the dielectric film 212, or between the dielectric film 250 and the color filter film 260, like when the conductive film 240 is formed between the dielectric film 212 and the dielectric film 250, the conductive film 240 is formed on a flat surface and patterning can be made easier. The wire layer 204 may be formed above another substrate, and then the another substrate may be bonded to a substrate including a Si layer 203 in which the plurality of photodiodes 10a to 10d are formed to obtain a semiconductor substrate 202.

In addition, all solid imaging devices and all methods for fabricating a solid imaging device that include elements of the embodiments and of which design can be changed as appropriate by persons skilled in the art are included in the scope of the embodiments.

While techniques normally used in the semiconductor industry such as cleaning before and after treatment are not described for convenience of description, it is needless to say that such techniques are included in the scope of the embodiments.

While certain embodiments have been described, these embodiments have been presented by way of example only, and are not intended to limit the scope of the inventions. Indeed, the novel methods and devices described herein may be embodied in a variety of other forms; furthermore, various omissions, substitutions, and changes in the form of the methods and devices described herein may be made without departing from the spirit of the inventions. The accompanying claims and their equivalents are intended to cover such forms or modifications as would fall within the scope and spirit of the inventions.

What is claimed is:

1. A solid imaging device comprising:
a semiconductor substrate having a plurality of photoelectric conversion elements constituting a plurality of pixels formed therein, the semiconductor substrate having a first surface and a second surface opposite to the first surface and being equipped with a wire layer on a first surface side of the semiconductor substrate; and
a conductive film patterned and arranged above a border between pixels of the plurality of pixels on a second surface side of the semiconductor substrate, the conductive film being substantially transparent to visible light.

2. The device according to claim 1, wherein the conductive film is patterned in a grid shape.

3. The device according to claim 1, wherein the conductive film is patterned in a line shape.

4. The device according to claim 1, wherein an oxide containing indium (In) is used as a material of the conductive film.

5. The device according to claim 1, wherein the conductive film is formed to be in an electrically floating structure.

6. The device according to claim 1, wherein the conductive film is formed to be supplied with a predetermined potential.

7. The device according to claim 1, wherein the conductive film is patterned and arranged on a flat surface.

8. The device according to claim 1, further comprising: first and second dielectric films formed on the second surface side of the semiconductor substrate, wherein
the conductive film is arranged between the first and second dielectric films.

9. The device according to claim 1, further comprising: a microlens formed on the second surface side of the semiconductor substrate, wherein
the conductive film is arranged between the semiconductor substrate and the microlens.

10. The device according to claim 9, further comprising: an antireflection film formed on the second surface side of the semiconductor substrate, wherein
the conductive film is arranged between the antireflection film and the microlens.

11. The device according to claim 10, further comprising: a first dielectric film formed on the second surface side of the semiconductor substrate, wherein
the conductive film is arranged between the first dielectric film and the microlens.

12. The device according to claim 11, further comprising: a second dielectric film formed on the second surface side of the semiconductor substrate, wherein
the second dielectric film is formed between the conductive film and the microlens.

13. The device according to claim 12, further comprising: a color filter film formed on the second surface side of the semiconductor substrate, wherein
the color filter film is formed between the conductive film and the microlens.

14. The device according to claim 1, wherein the conductive film is formed in a pixel region.

15. The device according to claim 14, further comprising:
a light shielding film formed on the second surface side of the semiconductor substrate in a peripheral circuit region of the pixel region

16. The device according to claim 8, wherein the first and second dielectric films are formed in a pixel region and a peripheral circuit region of the pixel region.

17. The device according to claim 16, further comprising: a light shielding film formed on the second surface side of the semiconductor substrate in the peripheral circuit region of the pixel region, wherein
the light shielding film is formed between the first and second dielectric films.

18. The device according to claim 17, wherein the conductive film is formed in the pixel region and is not formed in the peripheral circuit region of the pixel region.

19. The device according to claim 1, wherein one of an InGaZnO film, an InZnO film, a ZnO film, an InO film, a GaZnO film, an indium tin oxide (ITO) film, a tin oxide (SnO₂) film, and a TiO₂ film is used as a material of the conductive film.

20. The device according to claim 10, wherein the conductive film is formed thicker than the antireflection film.
